(19) United States
(12) Patent Application Publication
(10) Pub. No.: US 2017/0313075 A1
(43) Pub. Date: Nov. 2, 2017

(54) INK JET HEAD AND INK JET RECORDING APPARATUS

(71) Applicant: TOSHIBA TEC KABUSHIKI KAISHA, Tokyo (JP)

(72) Inventors: Ryuichi ARAI, Numazu Shizuoka (JP); Ryutaro KUSUNOKI, Mishima Shizuoka (JP); Shuhei YOKOYAMA, Mishima Shizuoka (JP); Meng Fei WONG, Mishima Shizuoka (JP)

(21) Appl. No.: 15/428,894

(22) Filed: Feb. 9, 2017

(30) Foreign Application Priority Data
Apr. 27, 2016 (JP) 2016-089365

(51) Int. Cl. B41J 2/14; B41J 2/045; H01L 41/09

(52) U.S. Cl. CPC B41J 2/14233; H01L 41/0973; B41J 2/04541; B41J 2/04581

(57) ABSTRACT

According to an example, a base, a diaphragm, and a driving element are provided. The driving element includes a first electrode disposed on a second surface of the diaphragm, a second electrode opposing the first electrode, and a piezoelectric body interposed between the first electrode and the second electrode. In addition, an inter-wiring insulating film that covers the second surface of the diaphragm and the driving element, and an extracting electrode which is on the inter-wiring insulating film, are further provided. The inter-wiring insulating film includes a contact hole that exposes a part of the second electrode and through which the second electrode and the extracting electrode contact each other. The contact hole is disposed at a position which aligned with a solid portion of a circumferential wall of the pressure chamber in the base.

### CROSS-REFERENCE TO RELATED APPLICATION

This application is based upon and claims the benefit of priority from Japanese Patent Application No. 2016-089365, filed Apr. 27, 2016, the entire contents of which are incorporated herein by reference.

### FIELD

Embodiments described herein relate generally to an ink jet head and an ink jet recording apparatus.

### BACKGROUND

A so-called on-demand type ink jet recording method includes forming an image by ink droplets on a recording paper sheet by discharging the ink droplets from a nozzle according to an image signal. The on-demand type ink jet recording method includes a heat generation element type method and a piezoelectric element type method.

In the heat generation element type, a heat generating body that is on a flow path of ink generates bubbles in the ink. The ink droplets pressed by the bubbles are discharged from the nozzle. In the piezoelectric element type, as a piezoelectric element (piezo-element) is deformed, a pressure change is generated in the ink disposed in an ink chamber. Accordingly, the pressurized ink droplets are discharged from the nozzle.

The inkjet head that is an example of the piezoelectric element type has a driving element (piezoelectric element, actuator) that pressurizes the ink. The driving element includes, for example, a piezoelectric film and a metal electrode film formed on both surfaces of the piezoelectric film.

The ink jet head includes a pressure chamber that holds the ink therein. In one end portion of the pressure chamber, there is a diaphragm to which the driving element is attached. In the other end portion of the pressure chamber, there is a nozzle plate having the nozzle.

When a driving waveform (voltage) is applied to the two electrode films, an electric field in the direction that is the same as the direction of polarization is applied to the piezoelectric film via the electrode film. Accordingly, the driving element expands and contracts in the direction orthogonal to the electric field direction. The diaphragm is deformed by using the expansion and contraction. The pressure change is generated in the ink in the pressure chamber as the diaphragm is deformed, and the ink droplets are discharged from the nozzle.

### DESCRIPTION OF THE DRAWINGS

FIG. 1 is a sectional view illustrating an ink jet printer according to a first embodiment.

FIG. 2 is a plan view illustrating a main configuration of the ink jet head of the first embodiment.

FIG. 3A is a sectional view taken along line IIIA-IIIA of FIG. 2.

FIG. 3B is a sectional view taken along line IIIB-IIIB of FIG. 2.

FIGS. 4A-4C illustrate a manufacturing process of the ink jet head of the first embodiment, where:

FIG. 4A is a sectional view illustrating a state where an oxide film serving as a diaphragm and an on-substrate insulating film is formed in the entire region of a front surface of a silicon wafer;

FIG. 4B is a sectional view illustrating a state where a lower electrode, a piezoelectric film, and an upper electrode are stacked in order on the diaphragm and the on-substrate insulating film; and

FIG. 4C is a sectional view illustrating a state where the lower electrode, the piezoelectric film, and the upper electrode are patterned.

FIG. 5A is a sectional view illustrating a state where the inter-wiring insulating film is formed on the diaphragm, the on-substrate insulating film, and the driving element.

FIG. 5B is a sectional view illustrating a state where the inter-wiring insulating film is patterned.

FIG. 5C is a sectional view illustrating a state where the extracting electrode is formed.

FIG. 6A is a sectional view illustrating a state where a protection film is formed on the diaphragm, the on-substrate insulating film, the inter-wiring insulating film, and the extracting electrode.

FIG. 6B is a sectional view illustrating a state where a nozzle is formed by patterning the protection film.

FIG. 6C is a sectional view illustrating a state where an ink repellent film is formed on the protection film.

FIG. 7 is a sectional view illustrating a part of the ink jet head of the first embodiment.

FIG. 8 is a longitudinal sectional view illustrating a part of an ink jet head of a second embodiment.

### DETAILED DESCRIPTION

In a structure of an ink jet head having a configuration of the related art, a part at which a connection terminal is in contact with an external element for applying a voltage to the driving element is disposed to oppose a pressure chamber below the driving element. In this configuration, repeated stress is applied to a contact portion with the connection terminal by driving the driving element for a long period of time. Therefore, there is a possibility that cracks are generated in the film on which a driving portion is formed as the driving element is driven for a long period of time. In addition, there is a possibility that dielectric breakdown occurs as the current is concentrated in the crack portion, and the contact portion with the connection terminal becomes a connection failure. Therefore, apart at which the external element and the connection terminal are in contact with each other has a structure that is weak with respect to the stress at a position opposing the pressure chamber beneath the driving element, and deterioration of reliability of each driving element is caused in the contact portion with the connection terminal.

Embodiments provide an ink jet head and an ink jet recording apparatus which can prevent cracks caused by repeated stress of the driving element, and can improve reliability of each driving element.

In general, according to one embodiment, there is provided an ink jet head including: a base; a diaphragm; and a driving element. The base has a pressure chamber configured to hold ink. The diaphragm has a first surface that covers the pressure chamber and a second surface that is on a side opposite to the first surface. The driving element is disposed on the second surface of the diaphragm. The driving element is configured to discharge the ink from a nozzle in response to an applied voltage by deforming the diaphragm to change a volume of the pressure chamber. Furthermore, the driving element includes a first electrode disposed on the second surface of the diaphragm, a second electrode opposing the first electrode, and a piezoelectric body interposed between the first electrode and the second electrode. In addition, the ink jet head includes an inter-wiring insulating film that covers the second surface of the diaphragm and the driving element, and an extracting electrode disposed on the inter-wiring insulating film. The inter-wiring insulating film includes a contact hole that exposes a part of the second electrode and through which the second electrode and the extracting electrode contact each other. The contact hole is disposed at a position aligned with a solid portion of a circumferential wall of the pressure chamber in the base.

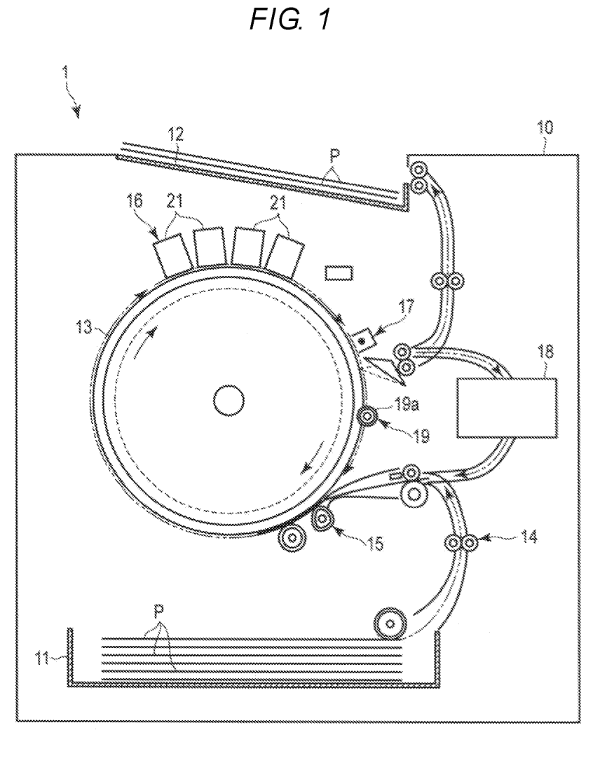

Hereinafter, a first embodiment will be described with reference to FIGS. 1 to 7. In addition, there is a case where an example of one or more other expressions is employed for each element that can be expressed in plural manners. However, this does not deny that different expressions of an element in which other expressions are not employed are employed, and does not limit other expressions that are not illustrated. In addition, each drawing schematically illustrates embodiments, and there is a case where a dimension of each element illustrated in the drawing is different from the description of the embodiment.

FIG. 1 is a sectional view illustrating an ink jet printer 1 according to the first embodiment. The ink jet printer 1 is an example of an ink jet recording apparatus . In addition, not being limited thereto, the ink jet recording apparatus may be other apparatuses, such as a copying machine.

As illustrated in FIG. 1, the inkjet printer 1 performs various processing, such as image forming, while conveying a recording paper sheet P which is a recording medium. The ink jet printer 1 includes a housing 10, a paper feeding cassette 11, a paper discharge tray 12, a holding roller (drum) 13, a conveying apparatus 14, a holding apparatus 15, an image forming apparatus 16, a removing peeling apparatus 17, a reversing apparatus 18, and a cleaning apparatus 19.

The paper feeding cassette 11 accommodates the plurality of recording paper sheets P, and is disposed in the housing 10. The paper discharge tray 12 is at an upper part of the housing 10. The recording paper sheet P on which the image forming is performed by the ink jet printer 1 is discharged to the paper discharge tray 12.

The conveying apparatus 14 has a plurality of guides and a plurality of conveying rollers that are disposed along a path in which the recording paper sheet P is conveyed. As the conveying roller is driven by a motor and rotates, the conveying roller conveys the recording paper sheet P from the paper feeding cassette 11 to the paper discharge tray 12.

The holding roller 13 has a cylindrical frame formed of a conductor, and a thin insulating layer formed on a front surface of the frame. The frame is grounded (ground connect). As the holding roller 13 rotates in a state where the recording paper sheet P is held on the front surface, the holding roller 13 conveys the recording paper sheet P.

The holding apparatus 15 causes the recording paper sheet P conveyed from the paper feeding cassette 11 by the conveying apparatus 14 to be adsorbed onto and held by the front surface (outer circumferential surface) of the holding roller 13. After pressing the recording paper sheet P to the holding roller 13, the holding apparatus 15 causes the recording paper sheet P to be adsorbed onto the holding roller 13 by an electrostatic force.

The image forming apparatus 16 forms an image on the recording paper sheet P held on the outer surface of the holding roller 13 by the holding apparatus 15. The image forming apparatus 16 has a plurality of ink jet heads 21 that face the front surface of the holding roller 13. The plurality of ink jet heads 21 form the image by respectively discharging four colors of ink, such as cyan, magenta, yellow, and black, to the recording paper sheet P.

The removing peeling apparatus 17 peels the recording paper sheet P on which the image is formed from the holding roller 13 by the removing the electrostatic charge. The removing peeling apparatus 17 removes electrostatic charge from the recording paper sheet P by supplying an electrical charge and inserting a claw into a space between the recording paper sheet P and the holding roller 13. Accordingly, the recording paper sheet P is peeled from the holding roller 13. The recording paper sheet P peeled from the holding roller 13 is conveyed to the paper discharge tray 12 or the reversing apparatus 18 by the conveying apparatus 14.

The cleaning apparatus 19 cleans the holding roller 13. The cleaning apparatus 19 is further on the downstream side than the electricity removing peeling apparatus 17 in the rotational direction of the holding roller 13. The cleaning apparatus 19 makes a cleaning member 19a abut against the front surface of the rotating holding roller 13, and cleans the front surface of the rotating holding roller 13.

The reversing apparatus 18 reverses the front and rear surfaces of the recording paper sheet P peeled from the holding roller 13, and supplies the recording paper sheet P onto the front surface of the holding roller 13 again. The reversing apparatus 18 reverses the recording paper sheet P by conveying the recording paper sheet P along a predetermined reversing path which, for example, reversely switches back the recording paper sheet P in the forward and rearward directions.

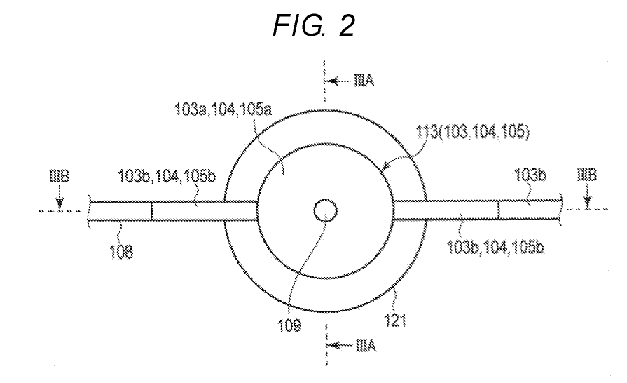

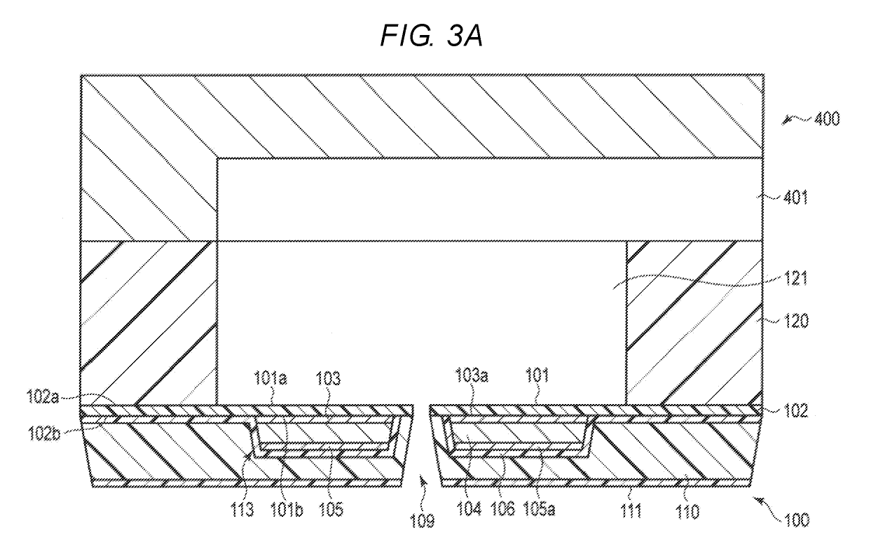

FIG. 2 is a plan view illustrating a main configuration of the ink jet head 21. FIG. 3A is a sectional view illustrating a part of the ink jet head 21 cut along line IIIA-IIIA of FIG. 2, and FIG. 3B is a sectional view illustrating a part of the ink jet head 21 cut along line IIIB-IIIB of FIG. 2. In addition, for the description, various elements that are normally hidden are illustrated by a solid line in FIG. 2.

The ink jet printer 1 includes a plurality of ink tanks (not illustrated) connected to the plurality of ink jet heads 21 and a plurality of control portions (not illustrated) . The ink jet head 21 is connected to the ink tank having an ink of a corresponding color.

The ink jet head 21 forms a character or an image by discharging ink droplets onto the recording paper sheet P held by the holding roller 13. The ink jet head 21 includes a nozzle plate 100, a pressure chamber structure body 120, and an ink flow path structure body 400. The pressure chamber structure body 120 is an example of a base.

The nozzle plate 100 is formed in a shape of a rectangular plate. The nozzle plate 100 is formed as an integrated structure on the pressure chamber structure body 120. The nozzle plate 100 includes a plurality of nozzles (orifice, ink discharge hole) 109, and a plurality of driving elements (piezoelectric element, actuator) 113. Each driving element 113 is configured of a lower electrode (first electrode) 103, a piezoelectric film (piezoelectric body) 104, and an upper electrode (second electrode) 105.

The nozzles 109 are circular holes. A diameter of each nozzle 109 is, for example, 20 μm. The nozzles 109 are disposed and aligned in a plurality of rows in the nozzle plate 100, and the driving elements 113 are disposed at high density.

The pressure chamber structure body 120 is a silicon wafer formed in a shape of a rectangular plate. The pressure chamber structure body 120 is not limited thereto, and for example, may be other semiconductors, such as silicon carbide (SiC) or germanium substrate. In addition, the base is not limited thereto, and may be formed of other materials, such as ceramics, glass, quartz, resin, or metal. The ceramic material used is, for example, nitride, carbide, or oxide, such as alumina ceramics, zirconia, silicon carbide, silicon nitride, or barium titanate. The resin used is, for example, a plastic material, such as acrylonitrile-butadiene-styrene (ABS), polyacetal, polyamide, polycarbonate, or polyether sulfone. The metal used is, for example, aluminum or titanium. The thickness of the pressure chamber structure body 120 is, for example, 725 μm. The thickness of the pressure chamber structure body 120 is, for example, in a range of 100 to 775 μm.

The pressure chamber structure body 120 has a plurality of pressure chambers (ink chambers) 121. As illustrated in FIG. 2, the pressure chamber 121 is a circular hole. A diameter of the pressure chamber 121 is, for example, 190 μm. In addition, the shape of the pressure chamber 121 is not limited thereto. The pressure chamber 121 passes through the pressure chamber structure body 120 in the thickness direction.

The plurality of pressure chambers 121 is disposed to correspond to the plurality of nozzles 109. Therefore, a corresponding nozzle 109 passes through a respective pressure chamber 121. Each pressure chamber 121 is linked to the outside of the ink jet head 21 via a respective nozzle 109.

The ink flow path structure body 400 is, for example, stainless steel formed in a shape of a rectangular plate. The material of the ink flow path structure body 400 is not limited to stainless steel. For example, the ink flow path structure body 400 may be formed of other materials, such as ceramics or resin. The ceramic material used is, for example, nitride, carbide, or oxide, such as alumina ceramics, zirconia, silicon carbide, or silicon nitride. The resin used is, for example, a plastic material, such as ABS, polyacetal, polyamide, polycarbonate, or polyether sulfone. The material of the ink flow path structure body 400 is selected considering a difference in expansion coefficient between the material and the nozzle plate 100, so as not to influence the generation of pressure for discharging the ink.

The ink flow path structure body 400 adheres to the pressure chamber structure body 120, for example, by an epoxy adhesive. The ink flow path structure body 400 has an ink flow path 401, as well as an ink supply port and an ink discharge port, which are not illustrated.

The ink flow path 401 is a groove formed on the front surface of the ink flow path structure body 400. The ink supply port opens to one end portion of the ink flow path 401. The ink supply port is connected to the ink tank, for example, via a tube. The ink tank is connected to the plurality of pressure chambers 121 via the ink flow path 401.

The ink of the ink tank flows into the ink flow path 401 through the ink supply port . The ink supplied to the ink flow path 401 is supplied to the plurality of pressure chambers 121. The ink that fills the pressure chamber 121 also flows into the nozzle 109 that is open to the pressure chamber 121. The ink jet printer 1 keeps the ink in the nozzle 109 by maintaining the pressure of the ink to be an appropriate negative pressure. The ink generates meniscus in the nozzle 109 and is prevented from leaking from the nozzle 109.

Next, the nozzle plate 100 will be described in detail. As illustrated in FIGS. 2, 3A, and 3B, the nozzle plate 100 has the above-described nozzle 109, a diaphragm 101, an on-substrate insulating film 102, the lower electrode 103, the piezoelectric film 104, the upper electrode 105, an inter-wiring insulating film 106, a protection film 110, and an ink repellent film 111. The inter-wiring insulating film 106 and the protection film 110 are an example of an insulating portion.

The diaphragm 101 and the on-substrate insulating film 102 are, for example, SiO₂ (silicon dioxide) formed in a shape of a rectangular plate in the pressure chamber structure body 120. For example, the diaphragm 101 and the on-substrate insulating film 102 are oxide films of the pressure chamber structure body 120, which is a silicon wafer. The diaphragm 101 and the on-substrate insulating film 102 may be formed of other materials, such as monocrystal Si (silicon), Al₂O₃ (aluminum oxide) , HfO₂ (hafnium oxide) , ZrO₂ (zirconium oxide), or diamond like carbon (DLC). The thickness of the diaphragm 101 and the on-substrate insulating film 102 is, for example, 4 μm. The thickness of the diaphragm 101 and the on-substrate insulating film 102 is approximately in a range of 1 μm to 50 μm. The diaphragm 101 and the on-substrate insulating film 102 are configured of the same film, and the name corresponds to an existence region. In other words, a region that is in contact with the pressure chamber 121 is the diaphragm 101, and a region that is in contact with the pressure chamber structure body 120 is the on-substrate insulating film 102.

The diaphragm 101 has a first surface 101a and a second surface 101b. The first surface 101a covers the plurality of pressure chambers 121. The second surface 101b is positioned on a side opposite to the first surface 101a.

The on-substrate insulating film 102 has the first surface 102a and the second surface 102b. The first surface 102a is fixed to the pressure chamber structure body 120. The second surface 102b is positioned on a side opposite to the first surface 102a.

The lower electrode 103 is formed on the second surface 101b of the diaphragm 101 and the second surface 102b of the on-substrate insulating film 102. The lower electrode 103 is a thin film made of, for example, Pt (platinum) and Al (aluminum).

The upper electrode 105 is formed on the piezoelectric film 104 such that the piezoelectric film 104 interposes apart of the lower electrode 103 and the upper electrode 105. The upper electrode 105 is a thin film made of, for example, Ti (titanium) and Pt. In addition, the lower electrode 103 and the upper electrode 105 maybe formed of other materials, such as Ni (nickel), Cu (copper), Al (aluminum), Ag (silver), Ti (titanium), W (tungsten), Mo (molybdenum), or Au (gold).

The thickness of each of the lower electrode 103 and the upper electrode 105 is, for example, 0.5 μm. The film thickness of each of the lower electrode 103 and the upper electrode 105 is approximately in a range of 0.01 to 1 μm.

As illustrated in FIGS. 2, 3A, and 3B, the driving element 113 includes a stacked body in which a part of the lower electrode 103, the piezoelectric film 104, and a part of the upper electrode 105 are stacked in order. The piezoelectric film 104 is interposed between the part of the lower electrode 103 and the part of the upper electrode 105. The upper electrode 105 is in contact with the inter-wiring insulating film 106. The driving element 113 generates a pressure in the ink of the corresponding pressure chamber 121 for discharging the ink droplets from the corresponding nozzle 109.

An electrode portion 103a of the lower electrode 103 is in contact with the piezoelectric film 104 and is disposed on the second surface 101b of the diaphragm 101. The electrode portion 103a of the lower electrode 103 is formed in an annular shape that surrounds the nozzle 109, and is positioned on the same axis as the nozzle 109. Furthermore, an outer diameter of the electrode portion 103a of the lower electrode 103 is, for example, 133 μm. An inner diameter of the electrode portion 103a of the lower electrode 103 is, for example, 30 μm.

In addition, as illustrated in FIG. 2, a part of the electrode portion 103a of the lower electrode 103 linearly extends to a side from an annular part (electrode portion 103a), and a linear extension portion 103b, which is an individual electrode portion, is formed on the on-substrate insulating film 102. As illustrated in FIG. 3B, the extension portion 103b extends to the on-substrate insulating film 102 side from the upper part of the diaphragm 101 and is also formed on the on-substrate insulating film 102.

As illustrated in FIGS. 2, 3A, and 3B, the piezoelectric film 104 surrounds the nozzle 109 and is formed in an annular shape to have the same size as that of the electrode portion 103a of the lower electrode 103. The piezoelectric film 104 is formed to be slightly smaller than the electrode portion 103a of the lower electrode 103, but may be greater than the electrode portion 103a of the lower electrode 103. The piezoelectric film 104 is positioned on the same axis as the nozzle 109. The piezoelectric film 104 covers the electrode portion 103a of the lower electrode 103. Furthermore, a part of the piezoelectric film 104 extends from the annular part and is also disposed on the extension portion 103b of the lower electrode 103 formed on the on-substrate insulating film 102.

The piezoelectric film 104 is a film made of lead zirconate titanate (PZT) which is a piezoelectric material. Alternatively, the piezoelectric film 104 may be formed of various other piezoelectric materials, such as PTO (PbTiO₃: lead titanate) , PMNT (Pb(Mg_{1/3}Nb_{2/3})O₃—PbTiO₃), PZNT (Pb(Zn_{1/3}Nb_{2/3})O₃—PbTiO₃) , ZnO, and AlN, for example.

The thickness of the piezoelectric film 104 is, for example, 2 μm. The thickness of the piezoelectric film 104 is determined, for example, by piezoelectric characteristics and dielectric breakdown voltage. The thickness of the piezoelectric film 104 is approximately in a range of 0.1 μm to 5 μm.

The piezoelectric film 104 generates polarization in the thickness direction. When an electric field in the direction that is the same as the direction of the polarization is applied to the piezoelectric film 104, the piezoelectric film 104 expands and contracts in the direction orthogonal to the direction of the electric field. In other words, the piezoelectric film 104 contracts or extends in the direction (in-plane direction) orthogonal to the film thickness.

In addition, in a case where ferroelectrics, such as PZT, are used as the piezoelectric film 104, polarization reversal is generated by applying the electric field in the direction opposite to the polarization direction. Therefore, in an embodiment, the electric field is practically applied only in the direction that is the same as the polarization direction. The piezoelectric film 104 extends in the film thickness direction by applying the electric field and contracts in the direction (in-plane direction) orthogonal to the film thickness.

The upper electrode 105 has an electrode portion 105a that surrounds the nozzle 109 and is formed in an annular shape to have the same size as that of the electrode portion 103a of the lower electrode 103 and the piezoelectric film 104. The upper electrode 105 is formed to be slightly smaller than the piezoelectric film 104, but may be greater than the piezoelectric film 104. The electrode portion 105a is positioned on the same axis as the nozzle 109. A part of the electrode portion 105a of the upper electrode 105 linearly extends to a side from the annular part (electrode portion 105a), and a linear extension portion 105b is formed on the on-substrate insulating film 102. The extension portion 105b extends to the on-substrate insulating film 102 side from the upper part of the diaphragm 101 and is also formed on the on-substrate insulating film 102. The upper electrode 105 covers the piezoelectric film 104. In other words, the upper electrode 105 is disposed on the discharge side (the side that is oriented to the outside of the ink jet head 21) of the piezoelectric film 104.

The piezoelectric film 104 is interposed between the electrode portion 103a of the lower electrode 103 and the electrode portion 105a of the upper electrode 105, as well as between the extension portion 103b of the lower electrode 103 and the extension portion 105b of the upper electrode 105. In other words, on the piezoelectric film 104, the electrode portion 103a of the lower electrode 103, and the electrode portion 105a of the upper electrode 105 overlap each other, and the extension portion 103b of the lower electrode 103 and the extension portion 105b of the upper electrode 105 overlap each other. The upper electrode 105 opposes the electrode portion 103a and the extension portion 103b of the lower electrode 103 via the piezoelectric film 104.

The inter-wiring insulating film 106 covers the second surface 101b of the diaphragm 101, the front surface of the driving element 113, and the electrode portion that is not in contact with the piezoelectric film 104 in the lower electrode 103. The inter-wiring insulating film 106 has a plurality of holes that exposes the connection portion with an external terminal of the lower electrode 103.

The inter-wiring insulating film 106 is formed of, for example, SiO₂. The inter-wiring insulating film 106 may be formed of other materials, such as SiN (silicon nitride) . The inter-wiring insulating film 106 has approximately uniform thickness on the second surface 101b of the diaphragm 101, the front surface of the driving element 113, and the extension portion 103b of the lower electrode 103. The thickness of the inter-wiring insulating film 106 is 1 μm, for example. The thickness of the inter-wiring insulating film 106 is approximately in a range of 0.1 μm to 5 μm, for example. In addition, the thickness of portions of the inter-wiring insulating film 106 may vary.

The inter-wiring insulating film 106 has a plurality of contact holes (contact portion) 107. As illustrated in FIG. 3B, each contact hole 107 is disposed at a position that is aligned with the solid portion of a circumferential wall of the pressure chamber 121 in the pressure chamber structure body 120. For example, the contact hole 107 can be disposed at a position between inner and outer edges of the circumferential wall of the pressure chamber 121. Each contact hole 107 is a hole for exposing a part of the upper electrode 105 provided on a region of the corresponding driving element 113 in which the on-substrate insulating film 102 exists. The contact hole 107 is formed in a shape of a circle, for example, having 20 μm of diameter.

As illustrated in FIGS. 2 and 3B, the upper electrode 105 is connected to an extracting electrode 108 via the contact hole 107. The extracting electrode 108 is provided on the inter-wiring insulating film 106, which prevents electric connection between the extracting electrode 108 and the lower electrode 103.

The protection film 110 is on the second surface 101b of the diaphragm 101. The protection film 110 is formed of a photosensitive polyimide, such as Photoneece® manufactured by Toray Industries, Inc. In other words, the protection film 110 is different from the inter-wiring insulating film 106 and is formed of a material having insulation. Not being limited thereto, the protection film 110 may be formed of other materials having insulation, such as resin or ceramics. The resin used is, for example, a plastic material, such as other types of polyimide, ABS, polyacetal, polyamide, polycarbonate, or polyether sulfone. The ceramic material used is, for example, is nitride or oxide, such as zirconia, silicon carbide, silicon nitride, or barium titanate. In addition, the protection film 110 may be formed of a metal material as long as the material has insulation between the driving element and the upper electrode 105. The metal material is, for example, aluminum, SUS, or titanium.

A material of the protection film 110 is selected considering heat resistance, insulation, thermal expansion coefficient, smoothness, and wettability with respect to the ink. In a case where the ink jet printer 1 uses ink having high conductivity, the insulation of the material can influence on degree of degeneration of the ink when the driving element 113 is driven.

The protection film 110 covers the second surface 101b of the diaphragm 101, the front surface of the inter-wiring insulating film 106, and a part of the extracting electrode 108. In other words, the protection film 110 covers the driving element 113 and the part of the lower electrode 103 from the upper part of the inter-wiring insulating film 106. The protection film 110 protects the driving element 113, the lower electrode 103, and the upper electrode 105, for example, from the ink or moisture in the air. The protection film 110 has a plurality of holes that respectively expose the connection portion connected with the plurality of external terminals of the lower electrode 103 and the upper electrode 105.

The material of the protection film 110 has a Young's modulus different from that of the material of the diaphragm 101. The Young's modulus of SiO₂, which forms the diaphragm 101, is 80.6 GPa. Meanwhile, the Young's modulus of polyimide, which forms the protection film 110, is 4 GPa. In other words, the Young's modulus of the protection film 110 is less than the Young's modulus of the diaphragm 101.

The front surface of the protection film 110 is formed to be approximately smooth, but has a fine unevenness. For example, at a part at which the driving element 113 is disposed, the front surface of the protection film 110 is uplifted compared to other pars. The front surface of the protection film 110 is positioned on a side opposite to the surface that adheres the diaphragm 101.

The thickness of the protection film 110 other than the part on which the driving element 113 is disposed, the lower electrode 103, and the extracting electrode 108, is approximately 4 μm. The film thickness of the protection film 110 is approximately in a range of 1 to 50 μm. The thickness of the protection film 110 is a distance from the second surface 101b of the diaphragm 101 to the front surface of the protection film 110. The thickness of the protection film 110 formed on the driving element 113 is approximately 2.5 μm. The thickness of the protection film 110 is a distance from the front surface of the inter-wiring insulating film 106 that is on the driving element 113 to the front surface of the protection film 110.

The ink repellent film 111 covers the protection film 110 and a part of the inter-wiring insulating film 106. The ink repellent film 111 is formed of an organic material containing fluorine having repellent characteristics or a silicone repellent material, such as Cytop® manufactured by Asahi Glass Co., Ltd. In addition, the ink repellent film 111 may be formed of other materials.

The ink repellent film 111 exposes an external connection terminal portion of the lower electrode 103 and an external connection terminal portion of the upper electrode 105 and exposes the protection film 110 without covering the protection film 110 on the circumferential side. The front surface of the ink repellent film 111 forms the front surface of the nozzle plate 100. The front surface of the ink repellent film 111 is positioned on a side opposite to the surface fixed to the protection film 110.

The thickness of the ink repellent film 111 is, for example, 1 μm. The thickness of the ink repellent film 111 is, for example, in a range of 0.01 to 10 μm. The thickness of the ink repellent film 111 at a part at which the driving element 113 is disposed, that is, a part at which there are the upper electrode 105 and the lower electrode 103, is less than that of other parts. In addition, the thickness of the ink repellent film 111 may also be constant.

When the ink droplets discharged from the nozzle 109 adhere to the vicinity of the nozzle 109, the stability of the ink discharge can deteriorate. The ink repellent film 111 prevents the ink droplets from adhering to the front surface of the nozzle plate 100.

The nozzle 109 penetrates the diaphragm 101, the protection film 110, and the ink repellent film 111. In other words, the nozzle 109 is formed in the diaphragm 101, the protection film 110, and the ink repellent film 111. Since the diaphragm 101 and the protection film 110 have ink-attracting characteristics (lyophilic characteristics), the meniscus of the ink contained in the pressure chamber 121 is maintained in the nozzle 109. Apart of the protection film 110 is interposed between the nozzle 109 and the inner circumferential surface of the driving element 113.

The control portion, which is not illustrated, is connected to the external connection terminal portion of the lower electrode 103, for example, via a flexible cable. The control portion is a microcomputer that controls an integrated circuit (IC), which in turn controls the ink jet head 21 or controls the ink jet printer 1. Meanwhile, the external connection terminal portion of the upper electrode 105 is connected to, for example, a GND (ground connection=0 V).

The control portion sends a signal for driving the corresponding driving element 113 to the lower electrode 103. The lower electrode 103 is used as an individual electrode for independently operating the plurality of driving elements 113.

The above-described ink jet head 21 performs printing (image forming), for example, as follows. By an operation of a user, a printing instruction signal is input to the control portion. The control portion applies the signal to the plurality of driving elements 113 based on the printing instruction. In other words, the control portion applies a driving voltage to the electrode portion that is in contact with the piezoelectric film 104 of the lower electrode 103.

When the signal is applied to the electrode portion 103a of the lower electrode 103, a potential difference is generated between the electrode portion 103a of the lower electrode 103 and the upper electrode 105. Accordingly, the electric field in the direction that is the same as the polarization direction is applied to the piezoelectric film 104, and the driving element 113 expands and contracts in the direction orthogonal to the electric field direction.

In the nozzle plate 100, in a case where the driving element 113 extends in the direction orthogonal to the electric field direction, the diaphragm 101 is curved so that the volume of the pressure chamber 121 is reduced. In contrast, in a case where the driving element 113 contracts in the direction orthogonal to the electric field direction, the diaphragm 101 is curved to enlarge the volume of the pressure chamber 121. At this time, the inter-wiring insulating film 106 and the protection film 110 interfere with the curve.

In particular, as illustrated in FIGS. 3A and 3B, the driving element 113 is disposed between the diaphragm 101 and a stack of the inter-wiring insulating film 106 and the protection film 110. Therefore, in a case where the driving element 113 extends in the direction orthogonal to the electric field direction, a force of deforming the shape into a recessed shape with respect to the pressure chamber 121 side is applied to the diaphragm 101. In other words, the diaphragm 101 is curved in the direction in which the volume of the pressure chamber 121 increases. In contrast, a force of deforming the shape into a projected shape with respect to the pressure chamber 121 side is applied to the inter-wiring insulating film 106 and the protection film 110. In other words, the inter-wiring insulating film 106 and the protection film 110 tend to curve in the direction in which the volume of the pressure chamber 121 is reduced.

Meanwhile, in a case where the driving element 113 contracts in the direction orthogonal to the electric field direction, a force of deforming the shape into a projected shape with respect to the pressure chamber 121 side is applied to the diaphragm 101. In other words, the diaphragm 101 tends to curve in the direction in which the volume of the pressure chamber 121 is reduced. In addition, a force of deforming the shape into a recessed shape with respect to the pressure chamber 121 side is applied to the inter-wiring insulating film 106 and the protection film 110. In other words, the inter-wiring insulating film 106 and the protection film 110 tend to curve in the direction in which the volume of the pressure chamber 121 is reduced.

As described above, the diaphragm 101 and the stack of the inter-wiring insulating film 106 and the protection film 110 tend to curve in the directions opposite to each other. In other words, the insulating portion formed by the inter-wiring insulating film 106 and the protection film 110 generates a force (film stress) that interferes with the deformation of the diaphragm 101 by the driving element 113.

An amount of deformation of a member of the driving element 113 influences the Young's modulus and the thickness of the member. The Young's modulus of polyimide, which forms the protection film 110, is less than the Young's modulus of SiO₂, which forms the diaphragm 101. Therefore, the amount of deformation of the protection film 110 is greater than the amount of deformation of the diaphragm 101 with respect to the same force. Furthermore, the inter-wiring insulating film 106 is thinner than the diaphragm 101. Therefore, the amount of deformation of the inter-wiring insulating film 106 is greater than the amount of deformation of the diaphragm 101 with respect to the same force.

As described above, the driving element 113 is operated in a bending mode (bending vibration). When the voltage is applied, the driving element 113 changes the volume of the pressure chamber 121 by deforming the diaphragm 101.

First, the driving element 113 increases the volume of the pressure chamber 121 by deforming the diaphragm 101 in a recessed shape with respect to the pressure chamber 121 side. Accordingly, a negative pressure is generated in the ink contained in the pressure chamber 121, and the ink flows into the pressure chamber 121.

Next, the driving element 113 reduces the volume of the pressure chamber 121 by deforming the diaphragm 101 into the projected shape with respect to the pressure chamber 121 side. Accordingly, the ink of the pressure chamber 121 is pressurized. Accordingly, the pressurized ink is discharged from the nozzle 109.

As a difference in Young's modulus between the diaphragm 101 and the protection film 110 increases, a voltage by which the ink discharge becomes possible can be decreased, and the inkjet head 21 can efficiently discharge the ink. Furthermore, as a difference in thickness between the insulating portion formed by the inter-wiring insulating film 106 and the protection film 110, and the diaphragm 101 increases, a voltage by which the ink discharge becomes possible can be decreased, and the ink jet head 21 can efficiently discharge the ink.

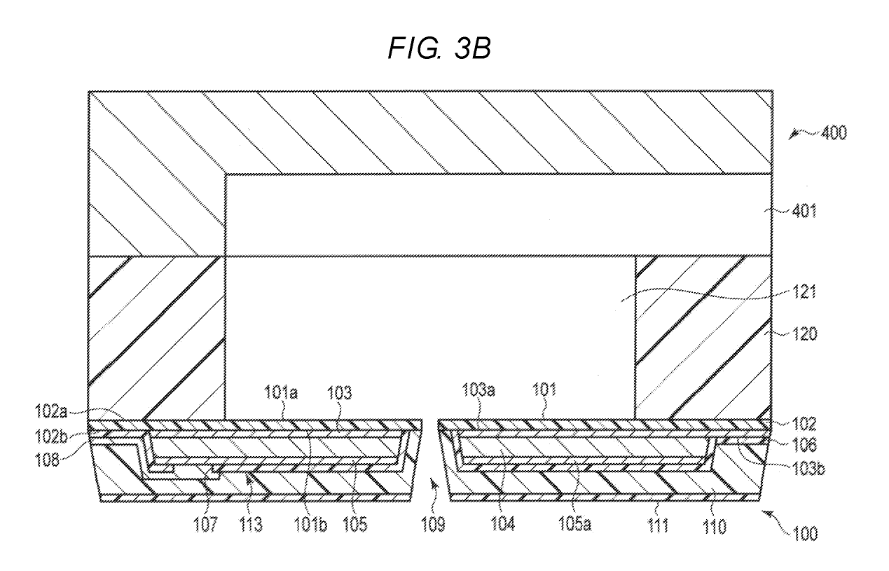

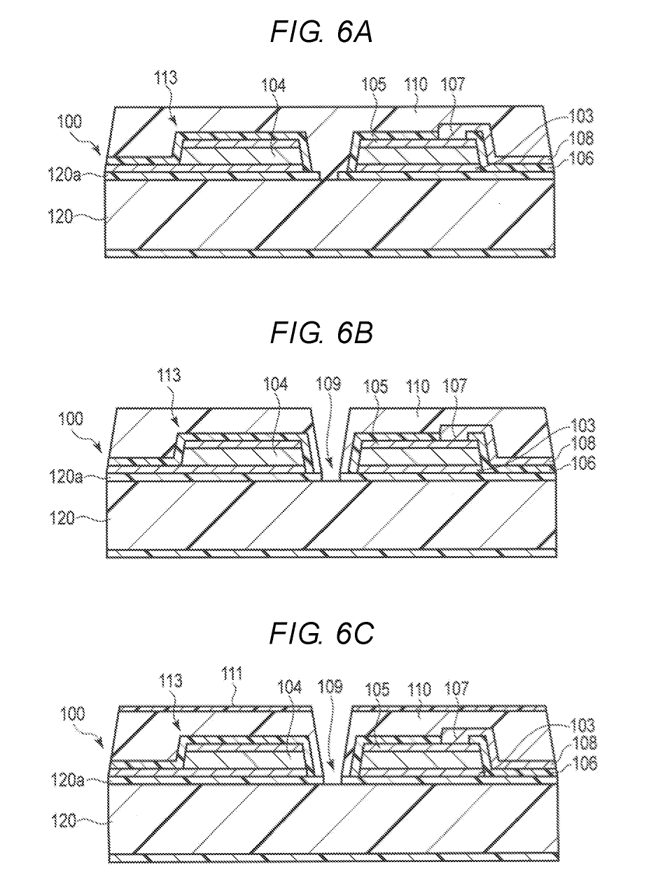

Next, an example method of manufacturing the ink jet head 21 will be described with reference to FIGS. 4A to 4C and 7. First, as illustrated in FIG. 4A, in the entire region of the front surface of the pressure chamber structure body 120 (silicon wafer) before the pressure chamber 121 is formed, an SiO₂ film 120a is formed as the diaphragm 101 and the on-substrate insulating film 102. The SiO₂ film 120a is formed, for example, by an oxidation film method. In addition, the SiO₂ film 120a may be formed by other methods, such as a chemical vapor deposition (CVD) method.

The silicon wafer that forms the pressure chamber structure body 120 is one large circular plate. The plurality of pressure chamber structure bodies 120 are cut from the silicon wafer in a subsequent step. In addition, not being limited thereto, one pressure chamber structure body 120 may be formed from one rectangular silicon wafer.

In a manufacturing process of the ink jet head 21, the silicon wafer is repeatedly heated and a thin film is formed. Therefore, the silicon wafer has heat resistance and becomes smooth according to a semiconductor equipment and materials international (SEMI) standard, and by mirror polishing.

Next, as illustrated in FIG. 4B, on the SiO₂ film 120a, a metal film that forms the lower electrode 103 is formed. First, a film of Ti and a film of Pt are sequentially formed by using a sputtering method. The film thickness of Pt is, for example, 0.45 μm, and the film thickness of Ti is, for example, 0.05 μm. In addition, the metal film may be formed by other manufacturing methods, such as evaporation or plating.

Next, the piezoelectric film 104 is formed on the metal film that forms the lower electrode 103. The piezoelectric film 104 is formed, for example, by a radio frequency (RF) magnetron sputtering method. At this time, the temperature of the silicon wafer is, for example, 350° C. After the piezoelectric film 104 is formed, in order to impart piezoelectricity to the piezoelectric film 104, heat processing is performed for three hours at 650° C. Accordingly, the piezoelectric film 104 obtains excellent crystallinity, and obtains excellent piezoelectric performance. The piezoelectric film 104 may be formed by other manufacturing methods, such as chemical vapor deposition method (CVD), sol-gel method, aerosol deposition method (AD method), or hydrothermal method.

Next, the metal film of Pt, which forms the upper electrode 105, is formed on the piezoelectric film 104. The metal film is formed, for example, by the sputtering method. The metal film may be formed by other manufacturing methods, such as vacuum deposition or plating.

Next, by etching the metal film of the above-described upper electrode 105 and the piezoelectric film 104, as illustrated in FIG. 4C, the upper electrode 105 and the piezoelectric film 104 are patterned. The patterning is performed by making an etching mask on the metal film of the upper electrode 105 and by removing the metal film and the piezoelectric film 104 except for the etching mask by the etching. The metal film and the piezoelectric film 104 may be patterned at the same time (together). Alternatively, the metal film and the piezoelectric film 104 may be separately patterned. The etching mask is formed by coating the film with a photosensitive resist, pre-baking, exposing using the mask in which a desirable pattern is formed, developing, and post-baking.

Next, the lower electrode 103 is formed by the patterning. The patterning is performed by making an etching mask on the piezoelectric film 104, the upper electrode 105, and the metal film (Pt/Ti) of the lower electrode 103 under the piezoelectric film 104, and by removing the metal film except for the etching mask by the etching. The etching mask is formed by coating the film with a photosensitive resist, pre-baking, exposing using the mask in which a desirable pattern is formed, developing, and post-baking.

The nozzle 109 is formed at the center of the annular part of the lower electrode 103, the upper electrode 105, and the piezoelectric film 104. At this time, a part at which the metal film and the piezoelectric film 104 are not present is formed in a circle concentric to the center of the annular part of the electrode portion 103a of the lower electrode 103, the electrode portion 105a of the upper electrode 105, and the piezoelectric film 104, and the extension portion 103b of the lower electrode 103 and the extension portion 105b of the upper electrode 105 are formed on the SiO₂ film 120a. In this manner, the driving element 113 is formed on the SiO₂ film 120a. By the patterning, the SiO₂ film 120a (the diaphragm 101 and the on-substrate insulating film 102) are exposed at the part other than the external connection terminal portion of the lower electrode 103, the upper electrode 105, and the driving element 113.

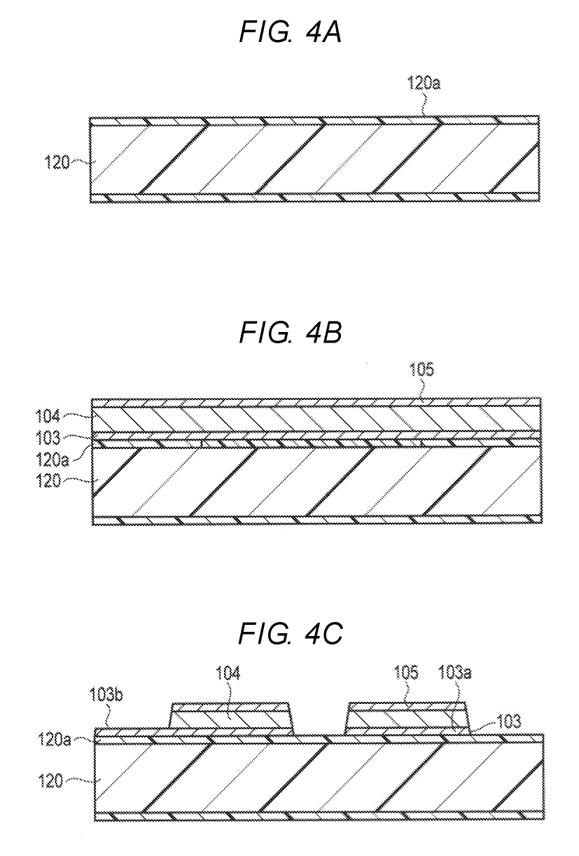

Next, as illustrated in FIG. 5A, the inter-wiring insulating film 106 is formed on the SiO₂ film 120a and the driving element 113. The inter-wiring insulating film 106 is formed by the CVD method, which can realize excellent insulation by forming the film at a low temperature. Not being limited thereto, the inter-wiring insulating film 106 may be formed by other methods, such as the sputtering method or evaporation.

As illustrated in FIG. 5B, the inter-wiring insulating film 106 is patterned after forming the film. Accordingly, in order to form the nozzle 109, a part 106a at which the inter-wiring insulating film 106 of the circle concentric to the center of the driving element 113 is not present, is formed. At the same time, the contact hole 107 is formed. A diameter of the part 106a at which the inter-wiring insulating film 106 is not present is, for example, 10 μm. The patterning is performed by removing the inter-wiring insulating film 106 except for the etching mask by the etching. The etching mask is formed by coating the film with a photosensitive resist, pre-baking, exposing using the mask in which a desirable pattern is formed, developing, fixing, and post-baking.

Next, as illustrated in FIG. 5C, the metal film that forms the extracting electrode 108 is formed on the inter-wiring insulating film 106. The metal film is a Ti(titanium)/Al(aluminum) thin film, for example, formed by the sputtering method. The film thickness of Ti is, for example, 0.1 μm, and the film thickness of Al is, for example, 0.4 μm. The metal film may be formed by other manufacturing methods, such as vacuum evaporation and plating. The metal film is connected to any of the lower electrode 103 and the upper electrode 105 through the contact hole 107.

By patterning the above-described metal film, the external connection terminal portion of the lower electrode 103 and the external connection terminal portion of the upper electrode 105 are formed. The patterning is performed by making an etching mask on the metal film and by removing the metal film except for the etching mask by the etching. The etching mask is formed by coating the film with a photosensitive resist, pre-baking, exposing using the mask in which a desirable pattern is formed, developing, and post-baking.

Next, the SiO₂ film 120a is patterned for forming the diaphragm 101 and a part of the nozzle 109 is formed. The patterning is performed by making an etching mask on the SiO₂ film 120a and by removing the SiO₂ film 120a except for the etching mask by the etching. The etching mask is formed by coating the diaphragm 101 with a photosensitive resist, pre-baking, exposing using the mask in which a desirable pattern is formed, developing, and post-baking.

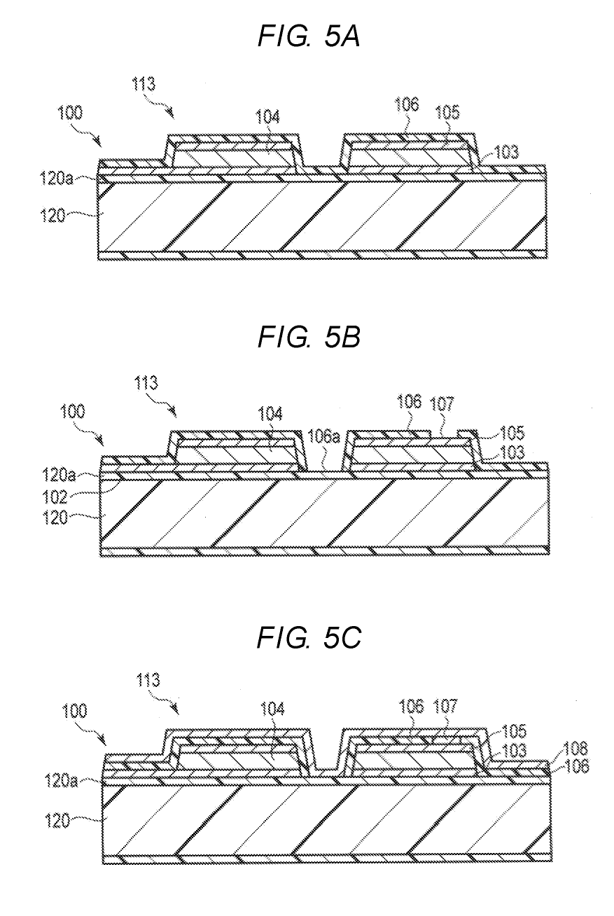

Next, as illustrated in FIG. 6A, the protection film 110 is formed by a spin coating method (spincoat) on the SiO₂ film 120a, the inter-wiring insulating film 106, and the extracting electrode 108. In other words, the protection film 110, which covers the inter-wiring insulating film 106, is formed. First, the SiO₂ film 120a and the inter-wiring insulating film 106 are covered with solution containing a polyimide precursor. Next, the silicon wafer is rotated and a solution front surface becomes smooth. By performing thermal polymerization and solvent removal by baking, the protection film 110 is formed.

A forming method of the protection film 110 is not limited to the spin coating method. The protection film 110 may be formed by other methods, such as CVD, vacuum evaporation, or plating.

As illustrated in FIG. 6B, by patterning the protection film 110, the nozzle 109 is formed, and the external connection terminal portion of the lower electrode 103 and the external connection terminal portion of the upper electrode 105 are exposed. The patterning is performed in order which corresponds to the material of the protection film 110.

As an example, a case where the protection film 110 is formed of non-photosensitive polyimide, such as Semiconfine® manufactured by Toray Industries, will be described. First, the solution containing the polyimide precursor forms a film on the inter-wiring insulating film 106 by the spin coating method, and sintering molding is performed by performing thermal polymerization and solvent removal by the baking. After this, the patterning is performed by making an etching mask on the non-photosensitive polyimide and by removing the polyimide film except for the etching mask by the etching. The etching mask is formed by coating the film with a non-photosensitive resist, pre-baking, exposing using the mask in which a desirable pattern is formed, developing, and post-baking.

As another example, a case where the protection film 110 is formed of photosensitive polyimide, such as Photoneece® manufactured by Toray Industries, will be described. First, after the solution forms a film on the inter-wiring insulating film 106 by the spin coating method, the pre-baking is performed. After this, the patterning is performed through the exposing using the mask and a developing process . In a case of positive type photosensitive polyimide, in the mask, a part which corresponds to the nozzle 109, the external connection terminal portion of the lower electrode 103, and the external connection terminal portion of the upper electrode 105 is open (light is transmitted). In a case of negative type photosensitive polyimide, in the mask, a part which corresponds to the nozzle 109, the external connection terminal portion of the lower electrode 103, and the external connection terminal portion of the upper electrode 105, is light-shielded. After this, the post-baking is performed and the protection film 110 is sintering molded.

Next, as illustrated in FIG. 6C, the ink repellent film 111 is formed on the protection film 110. The ink repellent film 111 is formed by spin coating a liquid ink repellent film material on the protection film 110.

Next, the film which forms the ink repellent film 111 is patterned. The patterning is performed by making an etching mask on the ink repellent film 111 and by removing the ink repellent film 111 except for the etching mask by the etching. The etching mask is formed by coating the ink repellent film 111 with a photosensitive resist, pre-baking, exposing using the mask in which a desirable pattern is formed, developing, and post-baking.

Next, a cover tape is attached onto the ink repellent film 111. The cover tape is, for example, a rear surface protection tape for chemical mechanical polishing (CMP) of the silicon wafer. The pressure chamber structure body 120 to which the cover tape is attached is vertically reversed, and as illustrated in FIG. 7, the plurality of pressure chambers 121 are formed in the pressure chamber structure body 120. The pressure chamber 121 is formed by the patterning. By forming the pressure chamber 121, a region that is in contact with the pressure chamber 121 in the SiO₂ film 120a becomes the diaphragm 101, and a region that is in contact with the pressure chamber structure body 120 becomes the on-substrate insulating film 102.

FIGS. 3A and 3B are sectional views illustrating the ink jet head 21 in which the insulating protection film 110 of the first embodiment is formed. Vertical depth dry etching (for an example, refer to Patent Cooperation Treaty (PCT) Publication No. WO 2003/030239), which is called Deep-RIE dedicated for a silicon substrate, is performed, the pressure chamber structure body 120 is etched, and the pressure chamber 121 is formed. At this time, a resist mask in which a desirable pattern is formed is provided on a rear surface of the pressure chamber structure body 120 that is the silicon wafer, and accordingly, the pressure chamber 121 is formed in the desirable pattern. The resist mask is formed by coating the film with a photosensitive resist, pre-baking, exposing using the mask in which a desirable pattern is formed, developing, and post-baking.

SF6 gas used in the etching does not show an etching action on the SiO₂ of the diaphragm 101 or polyimide of the protection film 110. Therefore, a process of the dry etching of the silicon wafer that forms the pressure chamber 121 is stopped by the SiO₂ film 120a of the diaphragm 101. In other words, the SiO₂ film 120a of the diaphragm 101 functions as a stop layer of the etching.

In addition, the above-described etching may use various methods, such as a wet etching method using chemicals or a dry etching method using plasma. Furthermore, the etching method or etching conditions maybe changed according to the material.

As described above, the process is performed from the process of forming the driving element 113 and the nozzle 109 on the diaphragm 101 of the SiO₂ film 120a to the process of forming the pressure chamber 121 in the pressure chamber structure body 120, by a film forming technology, a photolithography etching technology, and a spin coating method. Therefore, the nozzle 109, the driving element 113, and the pressure chamber 121 are precisely and easily formed on one silicon wafer.

Next, the cover tape is attached to a part of the protection film 110 to cover the external connection terminal portion of the lower electrode 103 and the external connection terminal portion of the upper electrode 105. The cover tape is formed of resin, and is easily attachable to and detachable from the protection film 110. The cover tape prevents contaminants from adhering to the external connection terminal portion of the lower electrode 103 and the external connection terminal portion of the upper electrode 105.

Next, the plurality of ink jet heads 21 is formed by dividing the silicon wafer. The ink jet head 21 is loaded on the inside of the ink jet printer 1. The control portion is connected to the external connection terminal portion of the lower electrode 103 and the external connection terminal portion of the upper electrode, for example, via a flexible cable.

Next, the ink flow path structure body 400 adheres to the rear surface of the pressure chamber structure body 120. In other words, the ink flow path structure body 400 adheres by the epoxy adhesive. Furthermore, the ink supply port and the ink discharge port of the ink flow path structure body 400 are connected to the ink tank, which is not illustrated, for example, via the tube.

As described above, in the embodiment, the nozzle plate 100 is made on the pressure chamber structure body 120. However, instead of making the nozzle plate 100 on the pressure chamber structure body 120, a part of the pressure chamber structure body 120 may be the diaphragm 101. For example, the driving element 113 is formed on one surface of the pressure chamber structure body 120, and a hole which corresponds to the pressure chamber 121 is formed from the other surface side. The hole does not penetrate the pressure chamber structure body 120. A thin layer remains on one surface side of the pressure chamber structure body 120, and the part is operated as the diaphragm 101.

According to the inkjet head 21 of the first embodiment, the contact hole 107 of the inter-wiring insulating film 106 is formed at a position separated from (not aligned with) the region in which the pressure chamber 121 of the pressure chamber structure body 120 exists. Accordingly, a connection portion between the upper electrode 105 and the extracting electrode 108 can be disposed at (aligned with) the solid portion of the pressure chamber structure body 120 where the pressure chamber 121 is not formed, which is a part having high rigidity. The solid portion of the pressure chamber structure body 120 that forms the circumferential wall portion of the pressure chamber 121 is a region that is hardly displaced when driving the driving element 113. As such, by providing the connection portion between the upper electrode 105 and the extracting electrode 108 in the region that opposes (is aligned with) the solid portion of the pressure chamber structure body 120, it is possible to alleviate the repeated stress that causes deterioration of reliability. Therefore, when driving each driving element 113, it is possible to mitigate or eliminate repeated stress applied to the connection portion between the upper electrode 105 and the extracting electrode 108. Therefore, it is possible to prevent cracks from being generated in the connection portion between the upper electrode 105 and the extracting electrode 108, to prevent dielectric breakdown from the cracks, and further, to prevent contact failure in the connection portion between the upper electrode 105 and the extracting electrode 108. As a result, it is possible to ensure reliability of the ink jet head 21 for a long period of time.

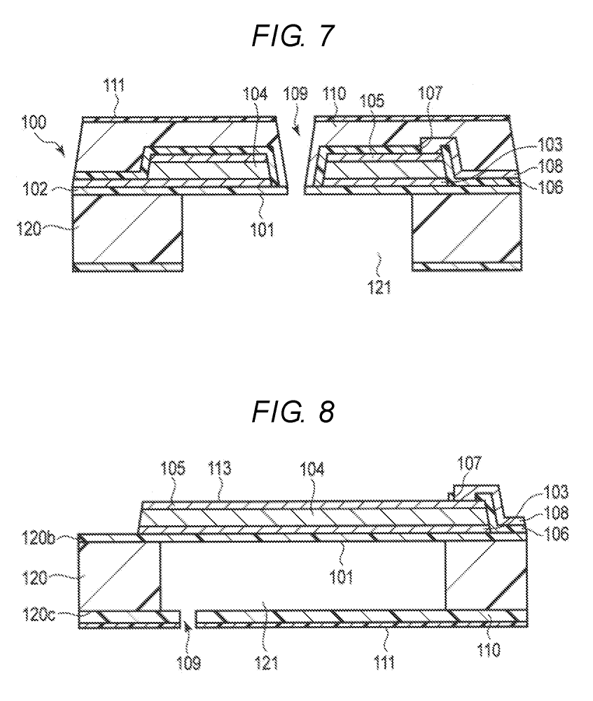

Next, with reference to FIG. 8, a second embodiment will be described. In an inkjet head 21 of the second embodiment, the driving element 113 is disposed on a first surface (upper surface in FIG. 8) 120b on the front surface side of the plate of the pressure chamber structure body 120, and the nozzle 109 is disposed on a second surface (lower surface in FIG. 8) 120c on the rear surface side of the plate of the pressure chamber structure body 120. Furthermore, similar to the first embodiment, the contact hole 107 through which the upper electrode 105 and the extracting electrode 108 of the driving element 113 make contact is disposed at (aligned with) the solid portion of the pressure chamber structure body 120 (where the pressure chamber 121 is not formed), which is a part having high rigidity.

Accordingly, it is possible to position the connection portion between the upper electrode 105 and the extracting electrode 108 over the solid portion of the pressure chamber structure body 120 that is the part having high rigidity where the pressure chamber 121 is not formed in the plate of the pressure chamber structure body 120. Therefore, similar to the first embodiment, in the second embodiment, by providing the connection portion between the upper electrode 105 and the extracting electrode 108 in the region which opposes the solid portion of the pressure chamber structure body 120, a structure in which the repeated stress is unlikely to be applied to the connection portion between the upper electrode 105 and the extracting electrode 108 is also achieved. Therefore, it is possible to prevent cracks from being generated in the connection portion between the upper electrode 105 and the extracting electrode 108, to prevent dielectric breakdown from the cracks, and further, to prevent contact failure in the connection portion between the upper electrode 105 and the extracting electrode 108. As a result, it is possible to ensure reliability of the ink jet head 21 for a long period of time.

According to the embodiments, it is possible to provide an ink jet head, an ink jet recording apparatus, and the manufacturing method of the ink jet head that can prevent cracks caused by the repeated stress of the driving element, and can improve reliability of each driving elements.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An ink jet head, comprising:
a base having a pressure chamber;
a diaphragm having a first surface that covers the pressure chamber and a second surface that is on a side opposite to the first surface;
a driving element disposed on the second surface of the diaphragm, the driving element configured to discharge ink held in the pressure chamber from a nozzle in response to an applied voltage by deforming the diaphragm to change a volume of the pressure chamber;
an inter-wiring insulating film that covers the second surface of the diaphragm and the driving element; and
an extracting electrode disposed on the inter-wiring insulating film,
wherein the driving element includes a first electrode disposed on the second surface of the diaphragm, a second electrode opposing the first electrode, and a piezoelectric body interposed between the first electrode and the second electrode,
wherein the inter-wiring insulating film includes a contact hole that exposes a part of the second electrode and through which the second electrode and the extracting electrode contact each other, and
wherein the contact hole is disposed at a position aligned with a solid portion of a circumferential wall of the pressure chamber in the base.

2. The ink jet head according to claim 1,
wherein a larger portion of the driving element overlaps the pressure chamber than overlaps the circumferential wall of the pressure chamber,
wherein the second electrode has an extension portion that overlaps the circumferential wall of the pressure chamber, and
wherein the contact hole is disposed over the extension portion of the second electrode.

3. The ink jet head according to claim 2,
wherein the base includes the pressure chamber formed therein by a through hole,
wherein the base includes the solid portion that forms the circumferential wall of the pressure chamber, and
wherein the extension portion of the second electrode overlaps the solid portion.

4. The ink jet head according to claim 1,
wherein the diaphragm is disposed on a front surface side of a plate of the base,
wherein the nozzle is disposed on a rear surface side of the plate of the base, and
wherein the pressure chamber extends between the front surface side and the rear surface side of the plate of the base.

5. The inkjet head according to claim 1, wherein the diaphragm is disposed on a front surface side of the base, and wherein the nozzle is disposed in the diaphragm.

6. The ink jet head according to claim 1, wherein the second electrode includes an annular portion surrounding the nozzle, and an extension portion that extends from the annular portion and overlaps the circumferential wall of the pressure chamber.

7. The ink jet head according to claim 6, where the contact hole is disposed over the extension portion of the second electrode.

8. The ink jet head according to claim 1, wherein the position of the contact hole is between inner and outer edges of the circumferential wall of the pressure chamber.

9. The ink jet head according to claim 1, further comprising:
a protection film disposed on the second surface of the diaphragm that covers the second surface of the diaphragm, the inter-wiring insulating film, and a portion of the extracting electrode.

10. An ink jet recording apparatus, comprising:
a holding apparatus configured to hold a recording medium on a front surface of a holding roller; and
an imaging forming apparatus including a plurality of ink jet heads facing the front surface of the holding roller, each of the plurality of ink jet heads comprising:
a base having a pressure chamber;
a diaphragm having a first surface that covers the pressure chamber and a second surface that is on a side opposite to the first surface;
a driving element disposed on the second surface of the diaphragm, the driving element configured to discharge ink held in the pressure chamber from a nozzle in response to an applied voltage by deforming the diaphragm to change a volume of the pressure chamber;
an inter-wiring insulating film that covers the second surface of the diaphragm and the driving element; and
an extracting electrode disposed on the inter-wiring insulating film,
wherein the driving element includes a first electrode disposed on the second surface of the diaphragm, a second electrode opposing the first electrode, and a piezoelectric body interposed between the first electrode and the second electrode,
wherein the inter-wiring insulating film includes a contact hole that exposes a part of the second electrode and through which the second electrode and the extracting electrode contact each other, and
wherein the contact hole is disposed at a position aligned with a solid portion of a circumferential wall of the pressure chamber in the base.

11. The inkjet recording apparatus according to claim 10,
wherein a larger portion of the driving element overlaps the pressure chamber than overlaps the circumferential wall of the pressure chamber,
wherein the second electrode has an extension portion that overlaps the circumferential wall of the pressure chamber, and
wherein the contact hole is disposed over the extension portion of the second electrode.

12. The inkjet recording apparatus according to claim 11,
wherein the base includes the pressure chamber formed therein by a through hole,
wherein the base includes the solid portion that forms the circumferential wall of the pressure chamber, and
wherein the extension portion of the second electrode overlaps the solid portion.

13. The ink jet recording apparatus according to claim 10,
wherein the diaphragm is disposed on a front surface side of a plate of the base,
wherein the nozzle is disposed on a rear surface side of the plate of the base, and
wherein the pressure chamber extends between the front surface side and the rear surface side of the plate of the base.

14. The ink jet recording apparatus according to claim 10, wherein the diaphragm is disposed on a front surface side of the base, and wherein the nozzle is disposed in the diaphragm.

15. The ink jet recording apparatus according to claim 10, wherein the second electrode includes an annular portion surrounding the nozzle, and an extension portion that extends from the annular portion and overlaps the circumferential wall of the pressure chamber.

16. The ink jet recording apparatus according to claim 15, where the contact hole is disposed over the extension portion of the second electrode.

17. The ink jet recording apparatus according to claim 10, wherein the position of the contact hole is between inner and outer edges of the circumferential wall of the pressure chamber.

18. The ink jet recording apparatus according to claim 10, further comprising:
a protection film disposed on the second surface of the diaphragm that covers the second surface of the diaphragm, the inter-wiring insulating film, and a portion of the extracting electrode.

19. A method of manufacturing an ink jet head, comprising:
forming a base having a pressure chamber containing ink;
forming a diaphragm having a first surface that covers the pressure chamber and a second surface that is on a side opposite to the first surface;
forming a driving element disposed on the second surface of the diaphragm, the driving element configured to discharge the ink from a nozzle in response to an applied voltage by deforming the diaphragm to change a volume of the pressure chamber;
forming an inter-wiring insulating film that covers the second surface of the diaphragm and the driving element; and
forming an extracting electrode disposed on the inter-wiring insulating film,
wherein the driving element includes a first electrode disposed on the second surface of the diaphragm, a second electrode opposing the first electrode, and a piezoelectric body interposed between the first electrode and the second electrode,
wherein the inter-wiring insulating film includes a contact hole that exposes a part of the second electrode and through which the second electrode and the extracting electrode contact each other, and
wherein the contact hole is disposed at a position aligned with a solid portion of a circumferential wall of the pressure chamber in the base.

20. The method of claim 19, wherein a larger portion of the driving element overlaps the pressure chamber than overlaps the circumferential wall of the pressure chamber, wherein the second electrode has an extension portion that overlaps the circumferential wall of the pressure chamber, and wherein the contact hole is disposed over the extension portion of the second electrode.
